(19) United States
(12) Patent Application Publication
(10) Pub. No.: US 2017/0345806 A1
(43) Pub. Date: Nov. 30, 2017

(54) SEMICONDUCTOR DEVICE AND METHOD OF MANUFACTURING SEMICONDUCTOR DEVICE

(71) Applicant: OLYMPUS CORPORATION, Tokyo (JP)

(72) Inventor: Yoshiaki Takemoto, Tokyo (JP)

(73) Assignee: OLYMPUS CORPORATION, Tokyo (JP)

(21) Appl. No.: 15/678,586

(22) Filed: Aug. 16, 2017

Related U.S. Application Data
(63) Continuation of application No. PCT/JP2015/056476, filed on Mar. 5, 2015.

(51) Int. Cl. H01L 25/18; H01L 23/528; H01L 23/522; H01L 23/532; H01L 21/321

(52) U.S. Cl. CPC H01L 25/18; H01L 23/53228; H01L 23/53214; H01L 21/3212; H01L 23/5226; H01L 23/528

(57) ABSTRACT

A semiconductor device includes a first substrate, an insulation layer, and a first electrode. The first substrate contains a first semiconductor material. The insulation layer includes a first surface, a second surface, and a third surface. The first electrode includes a fourth surface, a fifth surface, and a sixth surface, and contains a porous first conductive material. The second surface and the fifth surface configure the same surface. The third surface faces the sixth surface. A distance between the first surface and the first substrate is less than a distance between the second surface and the first substrate. A distance between the fourth surface and the first substrate is less than a distance between the fifth surface and the first substrate.

This application is a Continuation of International Patent Application No. PCT/JP2015/056476, filed on Mar. 5, 2015, the entire content of which is incorporated herein by reference.

### FIELD OF THE INVENTION

The present invention relates to a semiconductor device and a method of manufacturing a semiconductor device.

### DESCRIPTION OF RELATED ART

The performance of semiconductor devices has been improved by improvement of the two-dimensional integration rate. However, there is awareness of a limit in miniaturization technology and a limit in performance improvement by miniaturization. For this reason, three-dimensional integration has been proceeding as one means for improving performance. As such means, structures such as chip-on-board (COB), chip-on-chip (COC), chip-to-wafer (C2W), and wafer-to-wafer (W2W) have been studied. As a mounting method, a flip-chip method, wafer bonding, and the like are used. A method of connecting a plurality of substrates in a vertical direction using a bump electrode and a silicon through-electrode (TSV) is generally used. For example, attempts to realize a semiconductor device with higher performance have been made by stacking a plurality of semiconductor substrates while forming connection electrodes at a high density. In particular, devices with a stacked structure which include a plurality of semiconductor layers (a semiconductor memory, a semiconductor imaging device, and the like) have been developed.

In a technology for connecting a plurality of substrates as described above, measures against variations in the height of a bump electrode have been studied. For example, there is a method of flattening a bump electrode by applying a pressure at the time of mounting. However, excessive pressurization causes a distortion to remain in the bump electrode. This may lead to a malfunction. Therefore, there is a method of reducing a necessary pressure by using a planarization technology. In addition, a temperature cycle or stress caused by an impact may be applied in an actual use environment. For this reason, a technology for ensuring connection reliability of a bump electrode is required. For example, there is a technology for protecting a bump electrode by sealing around the electrode using an insulator such as resin.

As means for filling around the bump electrode with a resin material, there is a pre-coating method. In this method, at least one substrate is coated with a resin material before performing a process of bonding together two substrates on which an electrode is formed. Then, the two substrates are bonded together by a resin material.

However, in the pre-coating method, there is a possibility that resin may enter a connection surface between electrodes. Therefore, a contact resistance between electrodes may be increased or non-contact between electrodes may occur.

In view of the above, means for planarizing the surface of a substrate and exposing the surface of an electrode has been proposed. For example, there are means such as mechanical polishing, chemical mechanical polishing (CMP), cutting, and the like. In the technology disclosed in Japanese Unexamined Patent Application, First Publication No. 2012-69585, resin and electrodes are polished at the same time. Accordingly, a surface on which resin and electrodes are exposed is formed.

### SUMMARY OF THE INVENTION

According to a first aspect of the present invention, a semiconductor device includes a first substrate, an insulation layer, and a first electrode. The first substrate contains a first semiconductor material. The insulation layer includes a first surface, a second surface, and a third surface. The first electrode includes a fourth surface, a fifth surface, and a sixth surface, and contains a porous first conductive material. The second surface and the fifth surface configure the same surface. The third surface faces the sixth surface. A distance between the first surface and the first substrate is less than a distance between the second surface and the first substrate. A distance between the fourth surface and the first substrate is less than a distance between the fifth surface and the first substrate. The semiconductor device further includes a second substrate and a second electrode. The second substrate contains a second semiconductor material. The second electrode includes a seventh surface and an eighth surface and has a structure that is filled with a second conductive material. The fifth surface is electrically connected to the eighth surface. A distance between the seventh surface and the second substrate is less than a distance between the eighth surface and the second substrate.

According to a second aspect of the present invention, a semiconductor device includes a first substrate, an insulation layer, and a first electrode. The first substrate contains a first semiconductor material. The insulation layer includes a first surface, a second surface, and a third surface. The first electrode includes a fourth surface, a fifth surface, and a sixth surface, and contains a porous first conductive material. The second surface and the fifth surface configure the same surface. The third surface faces the sixth surface. A distance between the first surface and the first substrate is less than a distance between the second surface and the first substrate. A distance between the fourth surface and the first substrate is less than a distance between the fifth surface and the first substrate. The semiconductor device further includes a second substrate and a second electrode. The second substrate contains a second semiconductor material. The second electrode includes a seventh surface and an eighth surface and contains a porous second conductive material. The fifth surface is electrically connected to the eighth surface. A distance between the seventh surface and the second substrate is less than a distance between the eighth surface and the second substrate.

According to a third aspect of the present invention, in the first aspect, the semiconductor device may further include a metal film. The metal film contains a third conductive material and is in contact with the first surface, the second surface, and the third surface.

According to a fourth aspect of the present invention, in the third aspect, the first electrode and the metal film may contain the same metal.

According to a fifth aspect of the present invention, in the second aspect, the semiconductor device may further include a metal film. The metal film contains a third conductive material and is in contact with the first surface, the second surface, and the third surface.

According to a sixth aspect of the present invention, in the fifth aspect, the first electrode and the metal film may contain the same metal.

According to a seventh aspect of the present invention, a method of manufacturing a semiconductor device includes a first process, a second process, a third process, a fourth process, and a fifth process. In the first process, an insulation layer is formed on a first substrate containing a first semiconductor material. The insulation layer includes a first surface and a second surface. In the second process, a third surface is formed in the insulation layer by removing a portion of the insulation layer. In the third process, a conductive layer containing a first conductive material is formed on the second surface and the third surface. The conductive layer includes a fourth surface, a fifth surface, and a sixth surface. The second surface and the fifth surface configure the same surface. The third surface faces the sixth surface. A distance between the first surface and the first substrate is less than a distance between the second surface and the first substrate. A distance between the fourth surface and the first substrate is less than a distance between the fifth surface and the first substrate. In the fourth process, a porous first electrode is formed from the conductive layer. In the fifth process, the fifth surface and a first structure are bonded together. The first structure includes a second substrate and a second electrode. The second substrate contains a second semiconductor material. The second electrode includes a seventh surface and an eighth surface, and has a structure that is filled with a second conductive material. A distance between the seventh surface and the second substrate is less than a distance between the eighth surface and the second substrate. The fifth surface and the first structure are bonded so that the fifth surface is electrically connected to the eighth surface in the fifth process.

According to an eighth aspect of the present invention, a method of manufacturing a semiconductor device includes a first process, a second process, a third process, a fourth process, and a fifth process. In the first process, an insulation layer is formed on a first substrate containing a first semiconductor material. The insulation layer includes a first surface and a second surface. In the second process, a third surface is formed in the insulation layer by removing a portion of the insulation layer. In the third process, a conductive layer containing a first conductive material is formed on the second surface and the third surface. The conductive layer includes a fourth surface, a fifth surface, and a sixth surface. The second surface and the fifth surface configure the same surface. The third surface faces the sixth surface. A distance between the first surface and the first substrate is less than a distance between the second surface and the first substrate. A distance between the fourth surface and the first substrate is less than a distance between the fifth surface and the first substrate. In the fourth process, a porous first electrode is formed from the conductive layer. In the fifth process, the fifth surface and a structure are bonded. The structure includes a second substrate and a second electrode. The second substrate contains a second semiconductor material. The second electrode includes a seventh surface and an eighth surface and contains a porous second conductive material. A distance between the seventh surface and the second substrate is less than a distance between the eighth surface and the second substrate. The fifth surface and the structure are bonded so that the fifth surface is electrically connected to the eighth surface in the fifth process.

### BRIEF DESCRIPTION OF THE DRAWINGS

FIG. 1 is a sectional view of a semiconductor device according to a first embodiment of the present invention.

FIG. 2 is a plan view of the semiconductor device according to the first embodiment of the present invention.

FIG. 3 is a view which shows a method of manufacturing the semiconductor device according to the first embodiment of the present invention.

FIG. 4 is a view which shows the method of manufacturing the semiconductor device according to the first embodiment of the present invention.

FIG. 5 is a view which shows the method of manufacturing the semiconductor device according to the first embodiment of the present invention.

FIG. 6 is a view which shows the method of manufacturing the semiconductor device according to the first embodiment of the present invention.

FIG. 7 is a view which shows the method of manufacturing the semiconductor device according to the first embodiment of the present invention.

FIG. 8 is a view which shows the method of manufacturing the semiconductor device according to the first embodiment of the present invention.

FIG. 9 is a perspective view of a semiconductor device according to a second embodiment of the present invention.

FIG. 10 is a sectional view of the semiconductor device according to the second embodiment of the present invention.

FIG. 11 is a view which shows a method of manufacturing the semiconductor device according to the second embodiment of the present invention.

FIG. 12 is a sectional view of a semiconductor device according to a third embodiment of the present invention.

FIG. 13 is a sectional view of a solid-state imaging device according to a fourth embodiment of the present invention.

### DETAILED DESCRIPTION OF THE INVENTION

Embodiments of the present invention will be described with reference to the drawings.

### First Embodiment

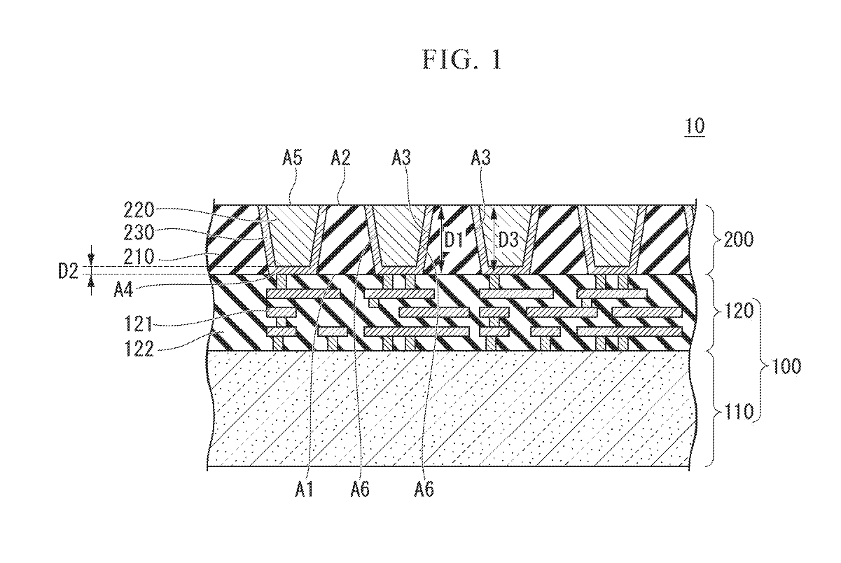

FIG. 1 shows a configuration of a semiconductor device 10 according to a first embodiment of the present invention. FIG. 1 shows a cross-section of the semiconductor device 10. As shown in FIG. 1, the semiconductor device 10 includes a first substrate 100 and a first connection layer 200.

The dimensions of portions configuring the semiconductor device 10 do not follow dimensions shown in FIG. 1. The dimensions of portions configuring the semiconductor device 10 may be arbitrary. In the present specification, an upward direction indicates an upward direction in a figure. In the same manner, a downward direction indicates a downward direction in a figure. The upward direction and the downward direction are not limited to specific directions.

The first substrate 100 includes a first semiconductor layer 110 and a first wiring layer 120. The first semiconductor layer 110 and the first wiring layer 120 are arranged in a direction (for example, a direction substantially perpendicular to the main surface) crossing a main surface (the widest surface among a plurality of surfaces configuring the surface of the substrate) of the first substrate 100. In addition, the first semiconductor layer 110 and the first wiring layer 120 are in contact with each other.

The first semiconductor layer 110 is made of a first semiconductor material. That is, the first substrate 100 includes the first semiconductor material. The first semiconductor material is at least one of silicon (Si), germanium (Ge), gallium (Ga), arsenic (As), and boron (B). The first semiconductor layer 110 includes a first surface and a second surface. The first surface of the first semiconductor layer 110 is in contact with the first wiring layer 120. The second surface of the first semiconductor layer 110 configures the main surface of the first substrate 100.

The first wiring layer 120 includes a first wiring 121 and a first interlayer insulation film 122. There are a plurality of first wirings 121 in FIG. 1, but a reference numeral of one of the first wirings 121 is shown as a representative.

The first wiring 121 is made of a conductive material (for example, a metal such as aluminum (Al) or copper (Cu)). The first wiring layer 120 includes a first surface and a second surface. The first surface of the first wiring layer 120 is in contact with the first connection layer 200. The second surface of the first wiring layer 120 is in contact with the first semiconductor layer 110. The first surface of the first wiring layer 120 configures one main surface of the first substrate 100.

The first wiring 121 is a thin film on which a wiring pattern is formed. The first wiring 121 transmits a signal. Only one layer of the first wiring 121 may be formed or multi-layers of the first wiring 121 may also be formed. In an example shown in FIG. 1, three layers of the first wiring 121 are formed. The multi-layers of the first wiring 121 are connected to each other by vias.

In the first wiring layer 120, portions other than the first wiring 121 are configured by the first interlayer insulation film 122. The first interlayer insulation film 122 is made of at least one of silicon dioxide (SiO2), silicon carbide-oxide (SiCO), silicon nitride (SiN), and the like.

At least one of the first semiconductor layer 110 and the first wiring layer 120 may include a circuit element such as a transistor.

The first connection layer 200 includes a first resin 210 (insulation layer), a first electrode 220, and a first metal film 230. There are a plurality of first resins 210 in FIG. 1, but a reference numeral of one of the first resins 210 is shown as a representative. There are a plurality of first metal films 230 in FIG. 1, but a reference numeral of one of the first metal films 230 is shown as a representative. There are a plurality of first electrodes 220 in FIG. 1, but a reference numeral of one of the first electrodes 220 is shown as a representative. The first resin 210, the first electrodes 220, and the first metal film 230 are disposed on the first surface of the first wiring layer 120. When the semiconductor device 10 is connected to another semiconductor device, the first connection layer 200 physically and electrically connects the semiconductor device 10 and another semiconductor device.

The first resin 210 is made of at least one of epoxy, benzocyclobutene, polyimide, polybenzoxazole, and the like. A photosensitive material may also be used when necessary. The first resin 210 includes a surface A1 (a first surface), a surface A2 (a second surface), and a surface A3 (a third surface). There are a plurality of surfaces A1 in FIG. 1, but a reference numeral of one of the surfaces A1 is shown as a representative. There are a plurality of surfaces A2 in FIG. 1, but a reference numeral of one of the surfaces A2 is shown as a representative. There are a plurality of surfaces A3 in FIG. 1, but a reference numeral of one of the surfaces A3 is shown as a representative.

The first resin 210 is an insulation layer including an insulator. The first resin 210 insulates the plurality of first electrodes 220 from each other. The first resin 210 is an example of the insulator. Instead of the first resin 210, an insulation layer including an insulator other than resin may also be disposed. For example, an insulation layer made of at least one of silicon dioxide (SiO2), silicon carbide-oxide (SiCO), silicon nitride (SiN), and the like may also be disposed.

The surface A1 faces in the opposite direction from the direction in which the surface A2 faces. The surface A1 is a lower surface of the first resin 210. The surface A2 is an upper surface of the first resin 210. The surface A3 is a side surface of the first resin 210. The surface A3 is connected to the surface A1 and the surface A2. The surface A1 is in contact with the first wiring layer 120. That is, the surface A1 is in contact with the first substrate 100. A distance between the surface A1 and the first wiring layer 120 is less than a distance D1 between the surface A2 and the first wiring layer 120. That is, the distance between the surface A1 and the first substrate 100 is less than the distance D1 between the surface A2 and the first substrate 100. The distance between the surface A1 and the first substrate 100 is zero in FIG. 1.

The first electrode 220 contains a porous first conductive material. The first conductive material is at least one of gold (Au), silver (Ag), copper (Cu), aluminum (Al), nickel (Ni), iron (Fe), and the like. The first electrode 220 includes a surface A4 (a fourth surface), a surface A5 (a fifth surface), and a surface A6 (a sixth surface). There are a plurality of surfaces A4 in FIG. 1, but a reference numeral of one of the surfaces A4 is shown as a representative. There are a plurality of surfaces A5 in FIG. 1, but a reference numeral of one of the surfaces A5 is shown as a representative. There are a plurality of surfaces A6 in FIG. 1, but a reference numeral of one of the surfaces A6 is shown as a representative.

The surface A4 faces in the opposite direction from the direction in which the surface A5 faces. The surface A4 is a lower surface of the first electrode 220. The surface A5 is an upper surface of the first electrode 220. The surface A6 is a side surface of the first electrode 220. The surface A6 is connected to the surface A4 and the surface A5. The surface A4 is in contact with the first metal film 230. A distance D2 between the surface A4 and the first wiring layer 120 is less than a distance D3 between the surface A5 and the first wiring layer 120. That is, the distance D2 between the surface A4 and the first substrate 100 is less than the distance D3 between the surface A5 and the first substrate 100.

The surface A3 faces the surface A6. The first metal film 230 is disposed between the surface A3 and the surface A6 in FIG. 1.

The surface A2 and the surface A5 configure the same surface. The surface A5 includes a surface of the first metal film 230. In a connection region in which the surface A2 and the surface A5 are connected, the distance D1 between the surface A2 and the first substrate 100 is the same as the distance D3 between the surface A5 and the first substrate 100. That is, the surface A2 and the surface A5 are smoothly connected. For this reason, when the semiconductor device 10 and another semiconductor device are bonded, an extra portion to be deformed is unnecessary. In addition, it is possible to form the first resin 210 and the first electrode 220 by planarization. In a region other than the connection region in which the surface A2 and the surface A5 are connected, the distance D1 between the surface A2 and the first substrate 100 may not be the same as the distance D3 between the surface A5 and the first substrate 100.

The semiconductor device 10 includes the first metal film 230. The first metal film 230 contains a third conductive material. The third conductive material is at least one of gold (Au), silver (Ag), copper (Cu), aluminum (Al), nickel (Ni), and the like. The first metal film 230 is in contact with the surface A3, the surface A4, and the surface A6. Furthermore, the first metal film 230 is in contact with the first wiring layer 120. That is, the first metal film 230 is in contact with the first substrate 100. The first metal film 230 is disposed to surround the first electrode 220. The first electrode 220 is formed using the first metal film 230 as a base at the time of manufacturing the semiconductor device 10.

The first metal film 230 is in contact with the first wiring 121. That is, the first metal film 230 is electrically connected to the first substrate 100. The first metal film 230 is in contact with the surface A4 and the surface A6. That is, the first metal film 230 is in contact with the first electrode 220. For this reason, the first electrode 220 is electrically connected to the first substrate 100 through the first metal film 230.

There may be a thin metal layer between the first metal film 230 and a base. The base is the surface A3 and the first wiring layer 120. This metal layer improves adhesion between the first metal film 230 and the base. This metal layer is made of at least one of titanium (Ti), chromium (Cr), and the like. A boundary between the first electrode 220 and the first metal film 230 is shown in FIG. 1. However, when the semiconductor device 10 and another semiconductor device are bonded by heating and pressurizing, the first electrode 220 and the first metal film 230 may also be integrated.

The surface A3 is inclined with respect to the main surface of the first substrate 100, that is, the first surface of the first wiring layer 120. For this reason, when the first electrode 220 is formed, a space (a hole) is unlikely to be formed in the first electrode 220.

The first electrode 220 and the first metal film 230 may contain the same metal. In other words, the first conductive material and the third conductive material may also be the same metal.

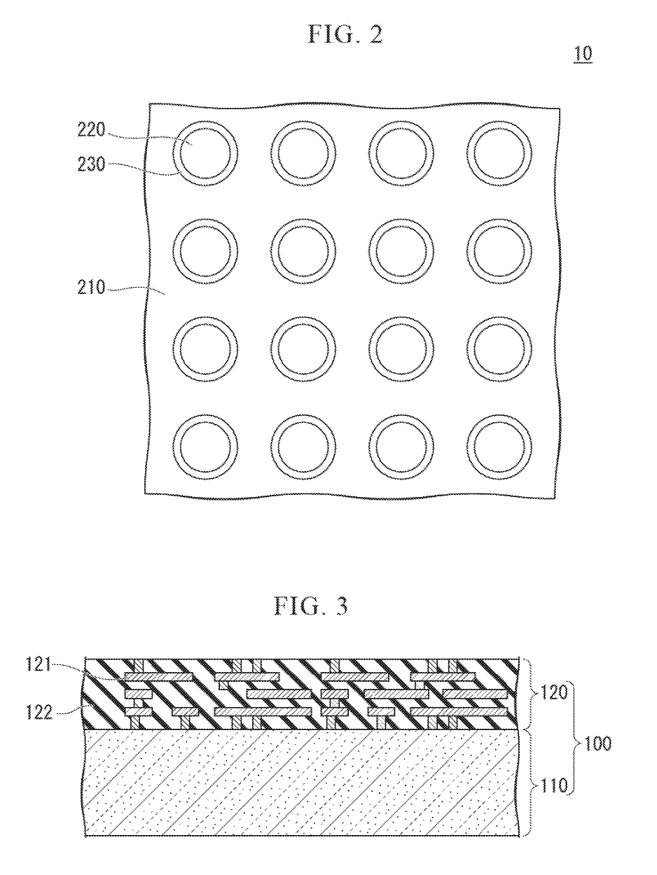

FIG. 2 shows an arrangement of the plurality of first electrodes 220 and a plurality of first metal films 230. FIG. 2 shows the semiconductor device 10 viewed in a direction perpendicular to the main surface of the first substrate 100. FIG. 2 shows a surface of the first connection layer 200. As shown in FIG. 2, the semiconductor device 10 includes the plurality of first electrodes 220 and the plurality of first metal films 230. Reference numerals of one of the first electrodes 220 and one of the first metal films 230 are shown as representatives in FIG. 2. The plurality of first electrodes 220 and the plurality of first metal films 230 are disposed in a matrix form. The plurality of first electrodes 220 is in a circular form. The shape of the plurality of first electrodes 220 may not be a circular. For example, the shape of the first electrodes 220 may also be in a polygonal form.

The surface A2 and the surface A5 are bonding surfaces. When the semiconductor device 10 and another semiconductor device are bonded, the surface A2 and the surface A5 are pressurized. Since the first electrode 220 is porous, the first electrode 220 is more likely to be deformed than an electrode with a structure that is filled with a conductive material. Therefore, while the first electrode 220 is deformed, the semiconductor device 10 and another semiconductor device are bonded. Both the first electrode 220 and the first resin 210 may also be deformed. Since at least the first electrode 220 is easily deformed, pressure required for bonding is reduced. Even when the surface A5 is not planar, adhesion between the surface A5 and another semiconductor device is maintained by deforming the first electrode 220.

In the region other than the connection region in which the surface A2 and the surface A5 are connected, heights of the surface A2 and the surface A5 may also be different from each other. For example, in the region other than the connection region, the distance D1 between the surface A2 and the first substrate 100 may also be less than the distance D3 between the surface A5 and the first substrate 100. In a region other than the connection region, the distance D1 between the surface A2 and the first substrate 100 may also be larger than the distance D3 between the surface A5 and the first substrate 100. In the region other than the connection region, the distance D1 between the surface A2 and the first substrate 100 may also be the same as the distance D3 between the surface A5 and the first substrate 100.

FIGS. 3 to 8 show a method of manufacturing the semiconductor device 10. With reference to FIGS. 3 to 8, the method of manufacturing the semiconductor device 10 will be described. In FIGS. 3 to 8, cross-sections of the first substrate 100 and the like are shown in the same manner as in FIG. 1. The method of manufacturing the semiconductor device 10 includes a preparation process, a process of forming a resin (a first process), a process of patterning a resin (a second process), a process of forming a conductive layer (a third process), and a process of forming an electrode (a fourth process).

### (Preparation Process)

As shown in FIG. 3, the first substrate 100 is prepared. Description of the method of manufacturing the first substrate 100 will be omitted.

### (Process of Forming a Resin)

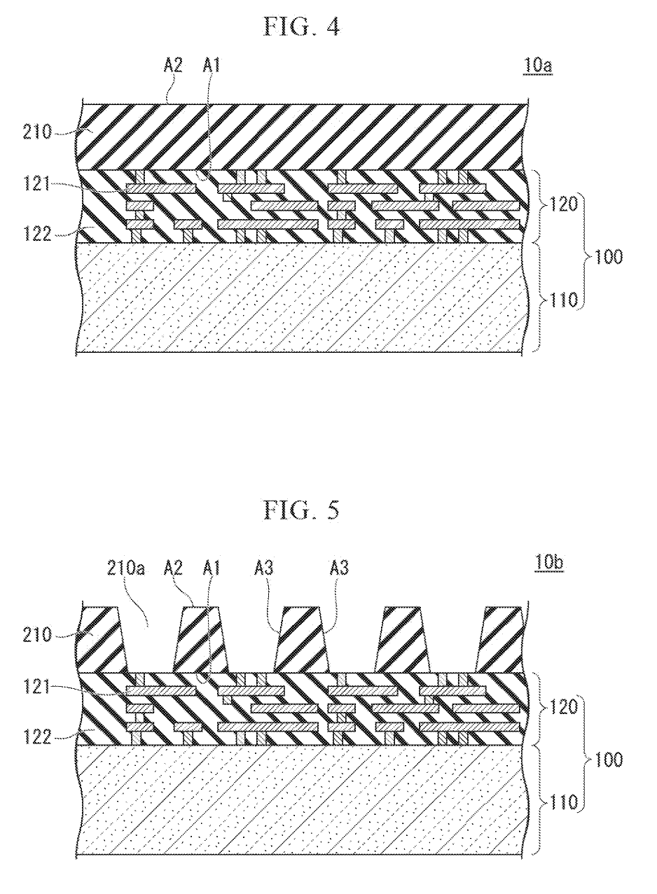

As shown in FIG. 4, the first resin 210 is formed on the first substrate 100 containing the first semiconductor material. For example, the first resin 210 is formed by a film-forming method such as spin coating or spray coating. The first resin 210 includes the surface A1 and the surface A2. An intermediate structure 10a is generated by the process of forming a resin.

### (Process of Patterning a Resin)

As shown in FIG. 5, a portion of the first resin 210 is removed, and thereby the surface A3 is formed in the first resin 210. An opening portion 210a is formed at an arbitrary position on the surface of the first resin 210 so that the first substrate 100 is exposed. For example, the opening portion 210a is formed by photolithography. It is possible to apply the photolithography used in general processes of manufacturing a semiconductor. For example, the first resin 210 has photosensitivity. Light in an arbitrary pattern is emitted to the surface A2 by using a stepper or a mask aligner. Then, only an exposed region in the first resin 210 is removed by using a developing material. It is possible to form an inclined surface A3 by adjusting an amount of light or adjusting at least one of time and temperature of development. An intermediate structure 10b is generated by the process of patterning a resin.

### (Process of Forming a Conductive Layer)

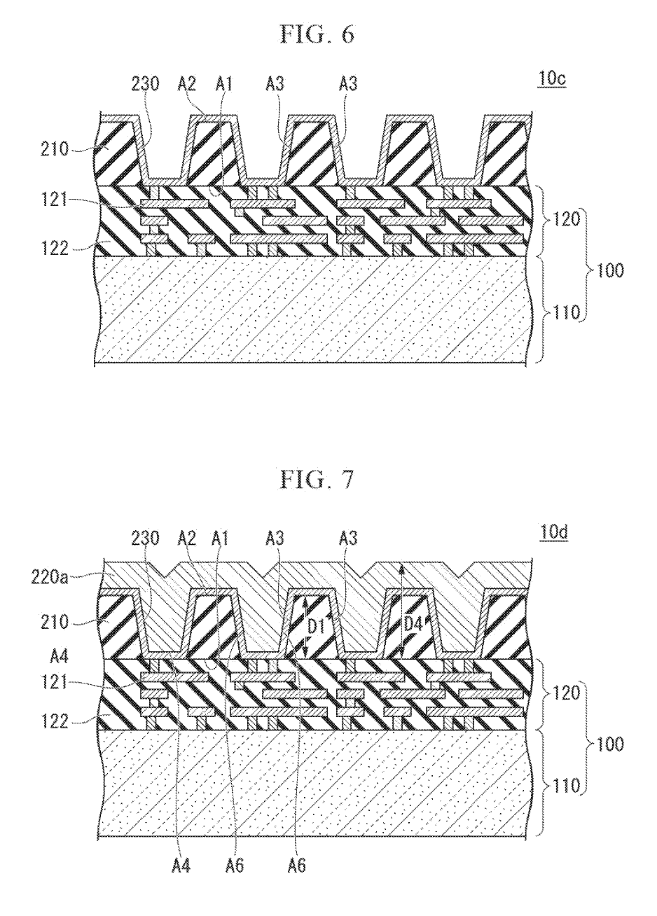

As shown in FIGS. 6 to 8, a conductive layer 220a including the first conductive material is formed on the surface A2 and the surface A3. The conductive layer 220a includes the surface A4, the surface A5, and the surface A6. The surface A2 and the surface A5 configure the same surface. The surface A3 faces the surface A6. The distance between the surface A1 and the first substrate 100 is less than the distance D1 between the surface A2 and the first substrate 100. The distance D2 between the surface A4 and the first substrate 100 is less than the distance D3 between the surface A5 and the first substrate 100. In FIGS. 6 to 8, the distance between the surface A1 and the first substrate 100 is zero.

The process of forming a conductive layer includes a process of forming the first metal film 230, a process of forming the conductive layer 220a, a planarization process, and a process of forming the first electrode 220.

In the process of forming the first metal film 230, the first metal film 230 including the third conductive material is formed on the surface A2 and the surface A3 as shown in FIG. 6. For example, the first metal film 230 is formed by a sputtering method or an evaporation method. An intermediate structure 10c is generated by the process of forming the first metal film 230.

In the process of forming the conductive layer 220a, the conductive layer 220a is formed on the first metal film 230 as shown in FIG. 7. The conductive layer 220a is formed to cover the opening portion 210a of the first resin 210. A distance D4 between the surface of the conductive layer 220a and the first substrate 100 is greater than the distance D1 between the surface A2 and the first substrate 100. The surface A4 and the surface A6 are formed by forming the conductive layer 220a. The conductive layer 220a is formed, and thereby the first metal film 230 is brought into contact with the surface A3, the surface A4, and the surface A6. The conductive layer 220a is formed by, for example, one of an electroplating method, an electroless plating method, a sputtering method, and the evaporation method.

The conductive layer 220a includes the first conductive material configuring the first electrode 220, and a material different from the first conductive material. The material different from the first conductive material is removed when the first electrode 220 is formed. For example, the conductive layer 220a is an alloy of gold (Au) and silver (Ag). The conductive layer 220a may be an alloy of iron (Fe) and manganese (Mn). The alloy of iron and manganese is obtained by mixing materials and heating the mixed materials. In addition, it is possible to form the alloy of iron and manganese by plating processing. The conductive layer 220a may be a metal which contains particles of resin. The conductive layer 220a may also be a metal containing spacer particles. It is possible to form a metal containing spacer particles by mixing a plurality of materials in a fine particle form and sintering the mixed materials. An intermediate structure 10d is formed by the process of forming the conductive layer 220a.

In the planarization process, the conductive layer 220a is planarized as shown in FIG. 8. The conductive layer 220a is scraped off so that the first resin 210 and the first metal film 230 are exposed. The conductive layer 220a is planarized, and thereby the surface A5 is formed. For example, the conductive layer 220a is scraped off by any one of chemical-mechanical polishing, mechanical polishing, a cutting method, and the like. When chemical-mechanical polishing is used, slurry is selected when required. After the conductive layer 220a is planarized, the surface A2 and the surface A5 configure the same surface. That is, the surface A2 and the surface A5 are smoothly connected. The distance D1 between the surface A2 and the first substrate 100 may be less than the distance D3 between the surface A5 and the first substrate 100. In this case, the first resin 210 is in a concave shape, and the first electrode 220 is in a convex shape. It is possible to form the surface A2 and the surface A5 in this manner by controlling an etching rate in the chemical-mechanical polishing. An intermediate structure 10e is generated by the planarization process.

In the process of forming the first electrode 220, the first electrode 220 is generated from the conductive layer 220a. The material different from the first conductive material is removed from the conductive layer 220a, and thereby the first electrode 220 is generated. For example, when the conductive layer 220a is an alloy of gold and silver, the intermediate structure 10e is immersed in a strong acid. Accordingly, silver is removed. When the conductive layer 220a is an alloy of iron and manganese, the first electrode 220 is generated by dissolving only manganese by electrolysis. When the conductive layer 220a is a metal containing spacer particles, the first electrode 220 is generated by removing the spacer particles. The semiconductor device 10 shown in FIG. 1 is generated by the process of forming the first electrode 220.

A semiconductor device according to each aspect of the present invention may not include a configuration corresponding to the first metal film 230. A method of manufacturing the semiconductor device according to each aspect of the present invention may not include a process corresponding to the process of forming the first metal film 230.

According to the first embodiment, the semiconductor device 10 is configured to include the first substrate 100, the first resin 210, and the first electrode 220.

According to the first embodiment, the method of manufacturing the semiconductor device 10 is configured to include the process of forming a resin (the first process), the process of patterning a resin (the second process), the process of forming a conductive layer (the third process), and the process of forming an electrode (the fourth process).

The semiconductor device 10 includes the first electrode 220 containing the porous first conductive material. For this reason, a pressure required for bonding is reduced.

The semiconductor device 10 further includes the first metal film 230. Therefore, the first electrode 220 is easily formed.

The first electrode 220 and the first metal film 230 may contain the same metal. Accordingly, conductivity between the first electrode 220 and the first metal film 230 is improved. In addition, an alloy of the first electrode 220 and the first metal film 230 is unlikely to be formed.

### Second Embodiment

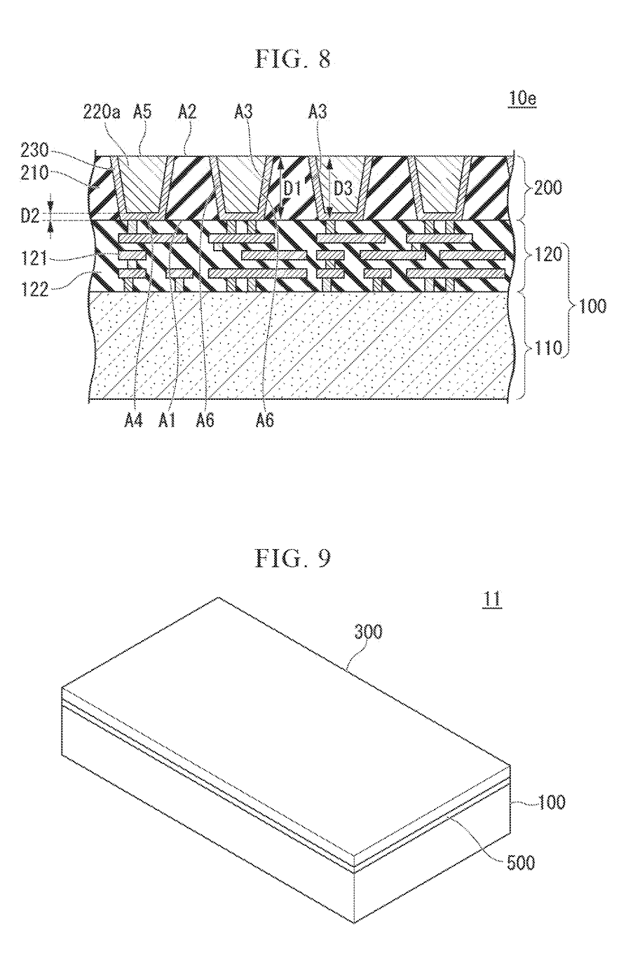

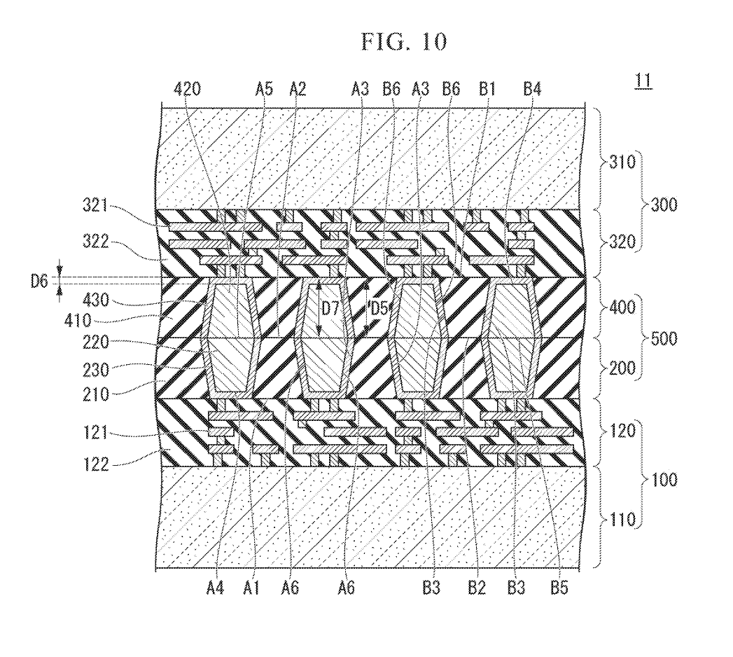

FIG. 9 shows a configuration of a semiconductor device 11 according to a second embodiment of the present invention. As shown in FIG. 9, the semiconductor device 11 includes a first substrate 100, a second substrate 300, and a connection portion 500. The first substrate 100 and the second substrate 300 are stacked with the connection portion 500 therebetween. FIG. 9 shows an example in which two substrates are stacked. The semiconductor device according to each aspect of the present invention may include three or more substrates. When the semiconductor device includes three or more substrates, two adjacent substrates correspond to the first substrate 100 and the second substrate 300. For example, when the semiconductor device includes three or more substrates, respective substrates are connected by a TSV.

FIG. 10 shows a configuration of the semiconductor device 11. FIG. 10 shows a cross-section of the semiconductor device 11.

Dimensions of portions configuring the semiconductor device 11 do not follow dimensions shown in FIG. 10. The dimensions of portions configuring the semiconductor device 11 may be arbitrary.

The first substrate 100 is the same as the first substrate 100 shown in FIG. 1. The connection portion 500) includes a first connection layer 200 and a second connection layer 400. The first connection layer 200 is the same as the first connection layer 200 shown in FIG. 1.

The second substrate 300 includes a second semiconductor layer 310 and a second wiring layer 320. The second semiconductor layer 310 and the second wiring layer 320 are arranged in a direction crossing the main surface of the second substrate 300. In addition, the second semiconductor layer 310 and the second wiring layer 320 are in contact with each other.

The second semiconductor layer 310 is formed from the second semiconductor material. That is, the second substrate 300 contains the second semiconductor material. The second semiconductor material is at least one of silicon (Si), germanium (Ge), gallium (Ga), arsenic (As), boron (B), and the like. The second semiconductor layer 310 includes a first surface and a second surface. The first surface of the second semiconductor layer 310 is in contact with the second wiring layer 320. The second surface of the second semiconductor layer 310 configures one main surface of the second substrate 300.

The second wiring layer 320 includes a second wiring 321 and a second interlayer insulation film 322. There are a plurality of second wirings 321 in FIG. 10, but a reference numeral of one of the second wirings 321 is shown as a representative.

The second wiring 321 is made of a conductive material (for example, a metal such as aluminum (Al) or copper (Cu)). The second wiring layer 320 includes a first surface and a second surface. The first surface of the second wiring layer 320 is in contact with the second connection layer 400. The second surface of the second wiring layer 320 is in contact with the second semiconductor layer 310. The first surface of the second wiring layer 320 configures one main surface of the second substrate 300.

The second wiring 321 is a thin film on which a wiring pattern is formed. The second wiring 321 transmits a signal. Only one layer of the second wiring 321 may be formed, and multi-layers of the second wiring 321 may also be formed. In an example shown in FIG. 10, three layers of the second wiring 321 are formed. The multi-layers of the second wiring 321 are connected by vias.

A portion other than the second wiring 321 in the second wiring layer 320 is configured by the second interlayer insulation film 322. The second interlayer insulation film 322 is made of at least one of silicon dioxide (SiO2), silicon carbide-oxide (SiCO), silicon nitride (SiN), and the like.

At least one of the second semiconductor layer 310 and the second wiring layer 320 may include a circuit element such as a transistor.

The second connection layer 400 includes a second resin 410 (an insulation layer), a second electrode 420, and a second metal film 430. There are a plurality of second resins 410 in FIG. 10, but a reference numeral of one of the second resins 410 is shown as a representative. There are a plurality of second electrodes 420 in FIG. 10, but a reference numeral of one of the second electrodes 420 is shown as a representative. There are a plurality of second metal films 430 in FIG. 10, but a reference numeral of one of the second metal films 430 is shown as a representative. The second resin 410, the second electrode 420, and the second metal film 430 are disposed on the first surface of the second wiring layer 320. The first connection layer 200 and the second connection layer 400 are physically and electrically connected to each other.

The second resin 410 is made of at least one of epoxy, benzocyclobutene, polyimide, polybenzoxazole, and the like. A photosensitive material may be also used when necessary. The second resin 410 includes a surface B1, a surface B2, and a surface B3. There are a plurality of surfaces B1 in FIG. 10, but a reference numeral of one of the surfaces B1 is shown as a representative. There are a plurality of surfaces B2 in FIG. 10, but a reference numeral of one of the surfaces B2 is shown as a representative. There are a plurality of surfaces B3 in FIG. 10, but a reference numeral of one of the surfaces B3 is shown as a representative.

The second resin 410 is an insulation layer including an insulator. The second resin 410 insulates the plurality of second electrodes 420. The second resin 410 is an example of the insulator. Instead of the second resin 410, an insulation layer including an insulator other than resin may also be disposed. For example, an insulation layer made of at least one of silicon dioxide (SiO2), silicon carbide-oxide (SiCO), silicon nitride (SiN), and the like may also be disposed.

The surface B1 faces in the opposite direction from the direction in which the surface B2 faces. The surface B1 is an upper surface of the second resin 410. The surface B2 is a lower surface of the second resin 410. The surface B3 is a side surface of the second resin 410. The surface B3 is connected to the surface B1 and the surface B2. The surface B1 is in contact with the second wiring layer 320. That is, the surface B1 is in contact with the second substrate 300. A distance between the surface B1 and the second wiring layer 320 is less than a distance D5 between the surface B2 and the second wiring layer 320. That is, the distance between the surface B1 and the second substrate 300 is less than the distance D5 between the surface B2 and the second substrate 300. The distance between the surface B1 and the second substrate 300 is zero in FIG. 10.

The second electrode 420 contains the porous second conductive material. The second conductive material is at least one of gold (Au), silver (Ag), copper (Cu), aluminum (Al), nickel (Ni), iron (Fe), and the like. The second electrode 420 includes a surface B4 (a seventh surface), a surface B5 (an eighth surface), and a surface B6. There are a plurality of surfaces B4 in FIG. 10, but a reference numeral of one of the surfaces B4 is shown as a representative. There are a plurality of surfaces B35 in FIG. 10, but a reference numeral of one of the surfaces B5 is shown as a representative. There are a plurality of surfaces B6 in FIG. 10, but a reference numeral of one of the surfaces B6 is shown as a representative.

The surface B4 faces in the opposite direction from the direction in which the surface B5 faces. The surface B4 is an upper surface of the second electrode 420. The surface B5 is a lower surface of the second electrode 420. The surface B6 is a side surface of the second electrode 420. The surface B6 is connected to the surface B4 and the surface B5. The surface B4 is in contact with the second metal film 430. A distance D6 between the surface B4 and the second wiring layer 320 is less than a distance D7 between the surface B5 and the second wiring layer 320. That is, the distance D6 between the surface B4 and the second substrate 300 is less than the distance D7 between the surface B5 and the second substrate 300.

The surface B3 and the surface B6 face each other. The second metal film 430 is disposed between the surface B3 and the surface B6 in FIG. 10. The surface A2 faces the surface B2. The surface A2 is in contact with the surface B2. The surface A5 is electrically connected to the surface B5. The surface A5 is in contact with the surface B5.

The surface B2 and the surface B5 configure the same surface. The surface B5 includes a surface of the second metal film 430. In a connection region in which the surface B2 and the surface B5 are connected, the distance D5 between the surface B2 and the second substrate 300 is the same as the distance D7 between the surface B5 and the second substrate 300. In other words, the surface B2 and the surface B5 are smoothly connected. For this reason, when the first connection layer 200 and the second connection layer 400 are bonded, an extra portion to be deformed is unnecessary. In addition, it is possible to form the second resin 410 and the second electrode 420 by planarization. In a region other than the connection region in which the surface B2 and the surface B5 are connected, the distance D5 between the surface 12 and the second substrate 300 may not be the same as the distance D7 between the surface B5 and the second substrate 300.

The semiconductor device 11 includes the second metal film 430. The second metal film 430 contains a fourth conductive material. The fourth conductive material is at least one of gold (Au), silver (Ag), copper (Cu), aluminum (Al), nickel (Ni), iron (Fe), and the like. The second metal film 430 is in contact with the surface B3, the surface B4, and the surface B6. Furthermore, the second metal film 430 is in contact with the second wiring layer 320. That is, the second metal film 430 is in contact with the second substrate 300. The second metal film 430 is disposed to surround the second electrode 420. The second electrode 420 is formed using the second metal film 430 as a base at the time of manufacturing the semiconductor device 11.

The second metal film 430 is in contact with the second wiring 321. In other words, the second metal film 430 is electrically connected to the second substrate 300. The second metal film 430 is in contact with the surface B4 and the surface B6. That is, the second metal film 430 is in contact with the second electrode 420. For this reason, the second electrode 420 is electrically connected to the second substrate 300 through the second metal film 430.

There may be a thin metal layer between the second metal film 430 and a base. The base is the surface B3 and the second wiring layer 320. This metal layer improves adhesion between the second metal film 430 and the base. This metal layer is made of at least one of titanium (Ti), chromium (Cr), and the like. A boundary between the second electrode 420 and the second metal film 430 is shown in FIG. 10. However, when the first connection layer 200 and the second connection layer 400 are bonded by heating and pressurizing, the second electrode 420 and the second metal film 430 may also be integrated.

The surface B3 is inclined with respect to the main surface of the second substrate 300, that is, the first surface of the second wiring layer 320. For this reason, when the second electrode 420 is formed, a space (a hole) is unlikely to be formed in the second electrode 420.

The second electrode 420 and the second metal film 430 may include the same metal. That is, the second conductive material and the fourth conductive material may also be the same metal.

The arrangement of the plurality of second electrodes 420 and the plurality of second metal films 430 viewed in a direction perpendicular to the main surface of the second substrate 300 is the same as the arrangement of the plurality of first electrodes 220 and the plurality of first metal films 230 viewed in a direction perpendicular to the main surface of the first substrate 100.

The surface A2 and the surface A5 are bonding surfaces. When the first connection layer 200 and the second connection layer 400 are bonded, the surface B2 and the surface B5 are pressurized. Since the second electrode 420 is porous, the second electrode 420 is more likely to be deformed than an electrode with a structure that is filled with a conductive material. For this reason, while the second electrode 420 is deformed, the first connection layer 200 and the second connection layer 400 are bonded. Both the second electrode 420 and the second resin 410 may also be deformed. Since at least the second electrode 420 is likely to be deformed, a pressure required for bonding is reduced. Even when the surface B5 is not planar, adhesion between the surface B5 and the surface A5 is maintained by deforming the second electrode 420.

In the region other than the connection region in which the surface B2 and the surface B5 are connected, heights of the surface B2 and the surface B5 may also be different from each other. For example, in the region other than the connection region, the distance D5 between the surface B2 and the second substrate 300 may also be less than the distance D7 between the surface B5 and the second substrate 300. In a region other than the connection region, the distance D5 between the surface B2 and the second substrate 300 may also be larger than the distance D7 between the surface B5 and the second substrate 300. In the region other than the connection region, the distance D5 between the surface B2 and the second substrate 300 may also be the same as the distance D7 between the surface B5 and the second substrate 300.

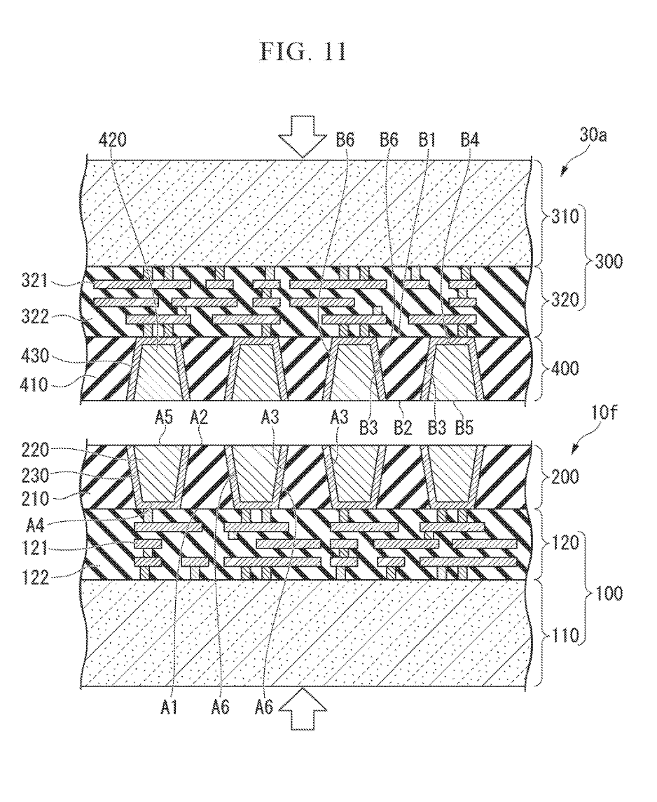

FIG. 11 shows a method of manufacturing the semiconductor device 11. With reference to FIG. 11, the method of manufacturing the semiconductor device 11 will be described. FIG. 11 shows a cross-section of the first substrate 100 and the like in the same manner as in FIG. 1. The method of manufacturing the semiconductor device 11 includes a process of forming a first structure 10f, a process of forming a second structure 30a, and a bonding process (a fifth process). The first structure 10f includes the first substrate 100 and the first connection layer 200. The second structure 30a includes the second substrate 300 and the second connection layer 400. The process of forming the first structure 10f and the process of forming the second structure 30a are the same as each process configuring the method of manufacturing the semiconductor device 10. That is, the process of forming the first structure 10f and the process of forming the second structure 30a include a preparation process, a process of forming a resin (a first process), a process of patterning a resin (a second process), a process of forming a conductive layer (a third process), and a process of forming an electrode (a fourth process).

The method of manufacturing the semiconductor device 11 includes a bonding process in which the surface A5 and the second structure 30a are bonded. That is, in the bonding process, the first structure 10f and the second structure 30a are bonded. As shown in FIG. 11, in the bonding process, the surface A5 and the second structure 30a are bonded so that the surface A2 faces the surface B2, and the surface A5 is electrically connected to the surface B5. In the bonding process, the surface A5 faces the surface B5. In the bonding process, the surface A2 and the surface B2 are bonded. In the bonding process, the surface A5 and the surface B5 are bonded. For example, a thermocompression bonding method is used in the bonding process. In the thermocompression bonding method, heat and pressure are applied. In the bonding process, a surface activation bonding method may also be used. In the surface activation bonding method, a surface is activated by emitting plasma onto the surface of a bonding surface, and then bonding is performed.

The semiconductor device according to each aspect of the present invention may not include a configuration corresponding to at least one of the first metal film 230 and the second metal film 430. The method of manufacturing the semiconductor device according to each aspect of the present invention may also not include a process corresponding to at least one of the process of forming the first metal film 230 and the process of forming the second metal film 430.

According to the second embodiment the semiconductor device 11 is configured to include the first substrate 100, the first resin 210, the first electrode 220, the second substrate 300, the second resin 410, and the second electrode 420.

According to the second embodiment, the method of manufacturing the semiconductor device 11 is configured to include the process of forming a resin (the first process), the process of patterning a resin (the second process), the process of forming a conductive layer (the third process), the process of forming an electrode (the fourth process), and the bonding process (the fifth process).

The semiconductor device 11 includes the first electrode 220 containing the porous first conductive material and a second electrode 420 containing the porous second conductive material. For this reason, pressure required for bonding is reduced.

The semiconductor device 11 further includes the second metal film 430. Therefore, the second electrode 420 is easily formed.

The second electrode 420 and the second metal film 430 may contain the same metal. Accordingly, conductivity between the second electrode 420 and the second metal film 430 is improved. In addition, an alloy of the second electrode 420 and the second metal film 430 is unlikely to be formed.

### Third Embodiment

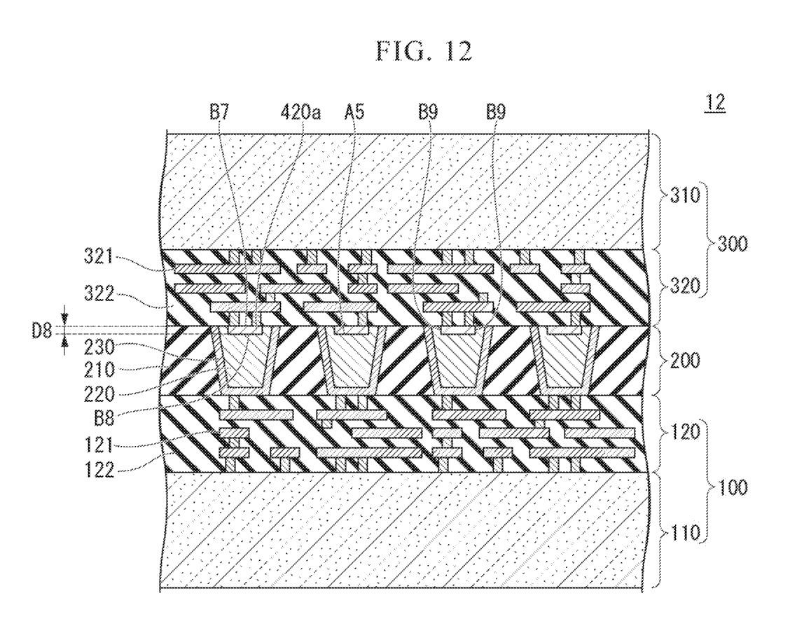

FIG. 12 shows a configuration of a semiconductor device 12 according to a third embodiment of the present invention. FIG. 12 shows a cross-section of the semiconductor device 12. As shown in FIG. 12, the semiconductor device 12 includes a first substrate 100, a second substrate 300, a first connection layer 200, and a second electrode 420a. The first substrate 100 and the second substrate 300 are stacked with the first connection layer 200 therebetween.

Dimensions of portions configuring the semiconductor device 12 do not follow dimensions shown in FIG. 12. The dimensions of portions configuring the semiconductor device 12 are arbitrary.

The first substrate 100 is the same as the first substrate 100 shown in FIG. 1. The first connection layer 200 is the same as the first connection layer 200 shown in FIG. 1 except that the second electrode 420a is disposed in the first connection layer 200. The second substrate 300 is the same as the second substrate 300 shown in FIG. 1.

There are a plurality of second electrodes 420a in FIG. 12, but a reference numeral of one of the second electrodes 420a is shown as a representative. The second electrode 420a is disposed on the first surface of the second wiring layer 320.

The second electrode 420a has a structure that is filled with a second conductive material. The second electrode 420a includes a surface B7 (a seventh surface), a surface B8 (an eighth surface), and a surface B9. There are a plurality of surfaces B7 in FIG. 12, but a reference numeral of one of the surfaces B7 is shown as a representative. There are a plurality of surfaces B8 in FIG. 12, but a reference numeral of one of the surfaces B8 is shown as a representative. There are a plurality of surfaces B9 in FIG. 12, but a reference numeral of one of the surfaces B9 is shown as a representative.

The surface B7 and the surface B8 face in opposite directions. The surface B7 is an upper surface of the second electrode 420a. The surface B8 is a lower surface of the second electrode 420a. The surface B9 is a side surface of the second electrode 420a. The surface B9 is connected to the surface B7 and the surface B8. A distance between the surface B7 and the second wiring layer 320 is less than a distance D8 between the surface B8 and the second wiring layer 320. That is, the distance between the surface B7 and the second substrate 300 is less than the distance D8 between the surface B8 and the second substrate 300. The distance between the surface B7 and the second substrate 300 is zero in FIG. 12.

The second electrode 420a is in contact with the second wiring 321. That is, the second electrode 420a is electrically connected to the second substrate 300. There may be a metal film between the surface B7 and the first surface of the second wiring layer 320.

The method of manufacturing the semiconductor device 12 includes a process of forming a first structure, a process of forming a second structure, and a bonding process (a fifth process). The first structure includes the first substrate 100 and the first connection layer 200. The second structure includes the second substrate 300 and the second electrode 420a. The process of forming a first structure is the same as each process configuring the method of manufacturing the semiconductor device 10. That is, the process of forming a first structure includes a preparation process, a process of forming a resin (a first process), a process of patterning a resin (a second process), a process of forming a conductive layer (a third process), and a process of forming an electrode (a fourth process). The process of forming a second structure includes the preparation process and the process of forming an electrode. In the process of forming an electrode in the process of forming a second structure, the second electrode 420a is formed.

In the bonding process, the first structure and the second structure are bonded. The surface A5 and the second structure are bonded so that the surface A5 is electrically connected to the surface B8 in the bonding process. The surface A5 faces the surface B8 in the bonding process.

The semiconductor device according to each aspect of the present invention may not include a configuration corresponding to the first metal film 230. The method of manufacturing the semiconductor device according to each aspect of the present invention may not include a process corresponding to the process of forming the first metal film 230.

According to the third embodiment, the semiconductor device 12 is configured to include the first substrate 100, a first resin 210, a first electrode 220, the second substrate 300, and the second electrode 420a.

According to the third embodiment, the method of manufacturing the semiconductor device 12 is configured to include the process of forming a resin (the first process), the process of patterning a resin (the second process), the process of forming a conductive layer (the third process), the process of forming an electrode (the fourth process), and the bonding process (the fifth process).

The semiconductor device 12 includes the first electrode 220 containing the porous first conductive material, and the second electrode 420a with a structure that is filled with the second conductive material. For this reason, pressure required for bonding is reduced.

### Fourth Embodiment

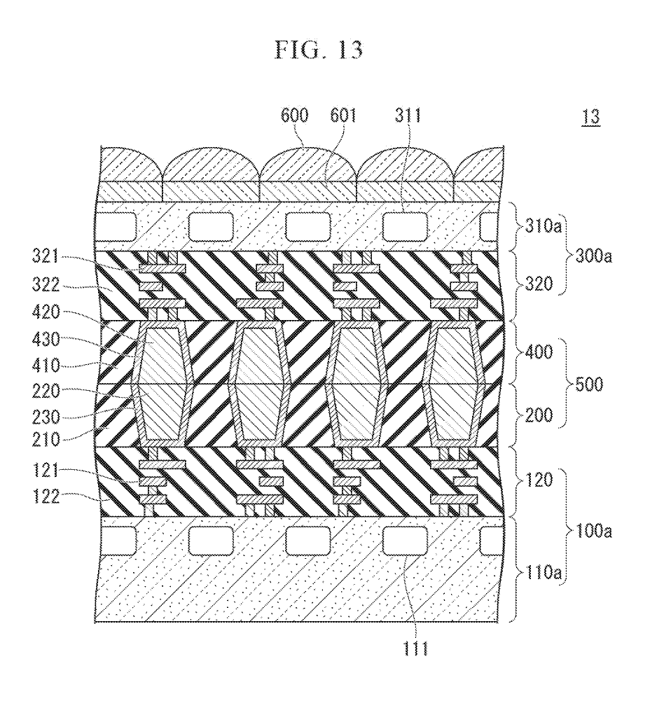

FIG. 13 shows a configuration of a solid-state imaging device 13 according to a fourth embodiment of the present invention. The solid-state imaging device 13 is a semiconductor device with an imaging function. FIG. 13 shows a cross-section of the solid-state imaging device 13. As shown in FIG. 13, the solid-state imaging device 13 includes a first substrate 100a, a second substrate 300a, a connection portion 500, a micro lens 600, and a color filter 601. The first substrate 100a and the second substrate 300a are stacked with the connection portion 500 therebetween.

Dimensions of portions configuring the solid-state imaging device 13 do not follow dimensions shown in FIG. 13. The dimensions of portions configuring the solid-state imaging device 13 may be arbitrary.

The first substrate 100a includes a first semiconductor layer 110a and a first wiring layer 120. The first wiring layer 120 is the same as the first wiring layer 120 shown in FIG. 1.

The first semiconductor layer 110a includes a first photoelectric conversion unit 111. There are a plurality of first photoelectric conversion units 111 in FIG. 13, but a reference numeral of one of the first photoelectric conversion units 111 is shown as a representative. The first semiconductor layer 110a is made of a first semiconductor material. For example, the first photoelectric conversion unit 111 is made of a semiconductor material whose impurity concentration is different from that of the first semiconductor material configuring the first semiconductor layer 110a.

The second substrate 300a includes a second semiconductor layer 310a and a second wiring layer 320. The second wiring layer 320 is the same as the second wiring layer 320 shown in FIG. 1.

The second semiconductor layer 310a includes a second photoelectric conversion unit 311. There are a plurality of second photoelectric conversion units 311 in FIG. 13, but a reference numeral of one of the second photoelectric conversion units 311 is shown as a representative. The second semiconductor layer 310a is made of a second semiconductor material. For example, the second photoelectric conversion unit 311 is made of a semiconductor material whose impurity concentration is different from that of the second semiconductor material configuring the second semiconductor layer 310a. The first photoelectric conversion unit 111 is formed in a region corresponding to the second photoelectric conversion unit 311. That is, the first photoelectric conversion unit 111 is formed at a position on which light which has passed through the second photoelectric conversion unit 311 is incident.

The color filter 601 is disposed on a surface of the second substrate 300a and the micro lens 600 is disposed on the color filter 601. There are a plurality of micro lenses 600 in FIG. 1, but a reference numeral of one of the micro lenses 600 is shown as a representative. In addition, there are a plurality of color filters 601 in FIG. 13, but a reference numeral of one of the color filters 601 is shown as a representative.

Light from an object that has passed through an imaging lens disposed at an optical front of the solid-state imaging device 13 is incident onto the micro lens 600. The micro lens 600 images the light which has passed through an imaging lens. The color filter 601 transmits light of a wavelength corresponding to a predetermined color.

Light which has passed through the micro lens 600 and the color filter 601 is incident onto the second semiconductor layer 310a. The light incident onto the second semiconductor layer 310a travels inside the second semiconductor layer 310a and is incident onto the second photoelectric conversion unit 311. The second photoelectric conversion unit 311 converts the incident light into a signal.

The light which has passed through the second photoelectric conversion unit 311 passes through the second wiring layer 320 and the connection portion 500, and is incident onto the first wiring layer 120 of the first substrate 100a. The light incident onto the first wiring layer 120 passes through the first wiring layer 120 and is incident onto the first semiconductor layer 110a. The light incident onto the first semiconductor layer 110a travels inside the first semiconductor layer 110a and is incident onto the first photoelectric conversion unit 111. The first photoelectric conversion unit 111 converts the incident light into a signal.

A structure of the connection portion 500 may be the same structure as that of the first connection layer 200 and the second electrode 420a shown in FIG. 12.

The solid-state imaging device 13 includes a first electrode 220 containing a porous first conductive material, and a second electrode 420 containing a porous second conductive material. For this reason, pressure required for bonding is reduced.

While preferred embodiments of the invention have been described and shown above, it should be understood that these are exemplary of the invention and are not to be considered as limiting. Additions, omissions, substitutions, and other modifications can be made without departing from the spirit or scope of the present invention. Accordingly, the invention is not to be considered as being limited by the foregoing description, and is only limited by the scope of the appended claims.

What is claimed is:

1. A semiconductor device, comprising:
a first substrate which contains a first semiconductor material;
an insulation layer which includes a first surface, a second surface, and a third surface; and
a first electrode which includes a fourth surface, a fifth surface, and a sixth surface, and contains a porous first conductive material;
wherein the second surface and the fifth surface configure the same surface,
the third surface faces the sixth surface,
a distance between the first surface and the first substrate is less than a distance between the second surface and the first substrate, and
a distance between the fourth surface and the first substrate is less than a distance between the fifth surface and the first substrate,
the semiconductor device further comprising:
a second substrate which contains a second semiconductor material; and
a second electrode which includes a seventh surface and an eighth surface and has a structure that is filled with a second conductive material,
wherein the fifth surface is electrically connected to the eighth surface, and
a distance between the seventh surface and the second substrate is less than a distance between the eighth surface and the second substrate.

2. A semiconductor device, comprising:
a first substrate which contains a first semiconductor material;
an insulation layer which includes a first surface, a second surface, and a third surface; and
a first electrode which includes a fourth surface, a fifth surface, and a sixth surface, and contains a porous first conductive material,
wherein the second surface and the fifth surface configure the same surface,
the third surface faces the sixth surface,
a distance between the first surface and the first substrate is less than a distance between the second surface and the first substrate, and
a distance between the fourth surface and the first substrate is less than a distance between the fifth surface and the first substrate,
the semiconductor device further comprising:
a second substrate which contains a second semiconductor material; and
a second electrode which includes a seventh surface and an eighth surface and contains a porous second conductive material,
wherein the fifth surface is electrically connected to the eighth surface, and
a distance between the seventh surface and the second substrate is less than a distance between the eighth surface and the second substrate.

3. The semiconductor device according to claim 1, further comprising:
a metal film which contains a third conductive material and is in contact with the first surface, the second surface, and the third surface.

4. The semiconductor device according to claim 3,
wherein the first electrode and the metal film contain the same metal.

5. The semiconductor device according to claim 2, further comprising:
a metal film which contains a third conductive material and is in contact with the first surface, the second surface, and the third surface.

6. The semiconductor device according to claim 5,
wherein the first electrode and the metal film contain the same metal.

7. A method of manufacturing a semiconductor device, comprising:
a first process in which an insulation layer is formed on a first substrate containing a first semiconductor material, the insulation layer including a first surface and a second surface;
a second process in which a third surface is formed in the insulation layer by removing a portion of the insulation layer;
a third process in which a conductive layer containing a first conductive material is formed on the second surface and the third surface, the conductive layer including a fourth surface, a fifth surface, and a sixth surface, the second surface and the fifth surface configuring the same surface, the third surface facing the sixth surface, a distance between the first surface and the first substrate being less than a distance between the second surface and the first substrate, and a distance between the fourth surface and the first substrate being less than a distance between the fifth surface and the first substrate;
a fourth process in which a porous first electrode is formed from the conductive layer; and
a fifth process in which the fifth surface and a first structure are bonded,
wherein the first structure includes
a second substrate which contains a second semiconductor material,
a second electrode which includes a seventh surface and an eighth surface, and has a structure that is filled with a second conductive material,
wherein a distance between the seventh surface and the second substrate is less than a distance between the eighth surface and the second substrate, and
the fifth surface and the first structure are bonded so that the fifth surface is electrically connected to the eighth surface in the fifth process.

8. A method of manufacturing a semiconductor device, comprising:
a first process in which an insulation layer is formed on a first substrate containing a first semiconductor material, the insulation layer including a first surface and a second surface;
a second process in which a third surface is formed in the insulation layer by removing a portion of the insulation layer;
a third process in which a conductive layer containing a first conductive material is formed on the second surface and the third surface, the conductive layer including a fourth surface, a fifth surface, and a sixth surface, the second surface and the fifth surface configuring the same surface, the third surface facing the sixth surface, a distance between the first surface and the first substrate being less than a distance between the second surface and the first substrate, and a distance between the fourth surface and the first substrate being less than a distance between the fifth surface and the first substrate;
a fourth process in which a porous first electrode is formed from the conductive layer; and
a fifth process in which the fifth surface and a structure are bonded,
wherein the structure includes
a second substrate containing a second semiconductor material, and
a second electrode which includes a seventh surface and an eighth surface and contains a porous second conductive material,
wherein a distance between the seventh surface and the second substrate is less than a distance between the eighth surface and the second substrate, and
the fifth surface and the structure are bonded so that the fifth surface is electrically connected to the eighth surface in the fifth process.
